(19) United States
(12) Patent Application Publication
(10) Pub. No.: US 2011/0175863 A1
(43) Pub. Date: Jul. 21, 2011

(54) DATA LINE DRIVER AND APPARATUSES HAVING THE SAME

(76) Inventor: Hyun Jin SHIN, Hwaseong-si (KR)

(21) Appl. No.: 13/007,047

(22) Filed: Jan. 14, 2011

(30) Foreign Application Priority Data
Jan. 19, 2010 (KR) 10-2010-0004644

(51) Int. Cl. G09G 5/00; H01L 25/00

(52) U.S. Cl. 345/204; 327/565

(57) ABSTRACT

A data line driver includes a first driver cell configured to drive a first data line connected to a first output pad. The first driver cell includes a first data register configured to latch first image data in response to a first latch clock signal, a first level shifter connected to the first data register, a first digital-analog converter (DAC) connected to the first level shifter, and a first amplifier connected between the first DAC and the first output pad. The first data register and the first amplifier are arranged in a first direction. The first level shifter and the first DAC are arranged adjacent to each other in a second direction and are arranged between the first data register and the first amplifier, and the second direction is perpendicular to the first direction.

### BACKGROUND

1. Field

Embodiments relate to a semiconductor layout, and more particularly, to a data line driver having a new architecture, and apparatuses including the data line driver.

2. Description of the Related Art

The data line driver, which is also called a source driver, drives source lines (or data lines) embodied on a display panel to display image data on the display panel. Data line drivers have an array architecture including a plurality of driver cells. Reduction of a pitch of a driver cell is effective to reduce the size of the data line driver including the driver cell. However, if the pitch is reduced to a limit value or smaller, the size of a long edge of the data line driver may be reduced, whereas the size of a short edge of the data line driver may be increased.

### SUMMARY

Embodiments provide a data line driver having a new layout, which is capable of reducing a length of the data line driver in a first direction, for example, a length of a short edge of the data line driver. Embodiments also provide a display device including the data line driver, and a display system including the display device.

According to an aspect of an exemplary embodiments, there is provided a data line driver including a first driver cell which drives a first data line connected to a first output pad. The first driver cell includes a first data register which latches first image data in response to a first latch clock signal; a first level shifter which is connected to the first data register; a first digital-analog converter (DAC) which is connected to the first level shifter; and a first amplifier which is connected between the first DAC and the first output pad.

The first level shifter and the first DAC are arranged adjacent to each other in a second direction perpendicular to a first direction between the first data register and the first amplifier that are arranged in the first direction. A sum of a pitch of the first level shifter and a pitch of the first DAC is less than or equal to a pitch of the first output pad.

The data line driver further includes a second driver cell which drives a second data line connected to a second output pad. The second driver cell includes a second data register which is disposed in the first direction and latches second image data in response to a second latch clock signal; a second level shifter which is connected to the second data register; a second DAC which is connected to the second level shifter; and a second amplifier which is disposed in the first direction and connected between the second DAC and the second output pad.

The first level shifter and the second level shifter are connected between the first DAC and the second DAC. The first level shifter and the second level shifter are arranged adjacent to each other to be symmetrical with each other with respect to the second direction.

A sum of a pitch of the first DAC, a pitch of the first level shifter, and a pitch of the second DAC is less than or equal to a pitch of the first output pad or a pitch of the second output pad. The first driver cell and the second driver cell are arranged to be symmetrical with each other with respect to the second direction.

According to an exemplary embodiment, there is provided a data line driver including a first driver cell and a second driver cell. The first driver cell includes a first DAC for supplying a digital-to-analog converted signal to a first data line, and a first level shifter for supplying a level-shifted signal to the first DAC. The second driver cell includes a second DAC for supplying a digital-to-analog converted signal to a second data line, and a second level shifter for supplying a level-shifted signal to the second DAC.

The first level shifter and the second level shifter adjacent to each other in a first direction are disposed between the first DAC and the second DAC that are arranged in a second direction perpendicular to the first direction. The first driver cell and the second driver cell are arranged adjacent to each other to be symmetrical with each other with respect to the second direction.

The first driver cell further includes a first amplifier which amplifies an output signal of the first DAC; and a first output pad which supplies a signal corresponding to a result of the amplification by the first amplifier to the first data line. The second driver cell further includes a second amplifier which amplifies an output signal of the second DAC; and a second output pad which supplies a signal corresponding to a result of the amplification by the second amplifier to the second data line. A sum of a pitch of the first DAC, a pitch of one of the first and second level shifters, and a pitch of the second DAC is less than or equal to a pitch of the first or second output pad.

According to an exemplary embodiment, there is provided a display device including the data line driver and a panel including the first data line.

According to an exemplary embodiment, there is provided a display system including the data line driver; a controller which controls an operation of the data line driver; and a panel including the first data line.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic block diagram of a display device including a data line driver, according to an exemplary embodiment;

FIG. 2 illustrates a layout of the data line driver included in the display device illustrated in FIG. 1, according to an exemplary embodiment;

FIG. 3 illustrates a layout of an exemplary data line driver;

FIG. 4 illustrates an embodiment of a detailed layout of the data line driver illustrated in FIG. 2;

FIG. 5 illustrates an exemplary embodiment of a detailed layout of the data line driver illustrated in FIG. 2;

FIG. 6 illustrates an exemplary embodiment of a detailed layout of the data line driver illustrated in FIG. 2;

FIG. 7 illustrates an exemplary circuit region of the data line driver illustrated in FIG. 6;

FIG. 8 illustrates a layout of the data line driver included in the display device illustrated in FIG. 1, according to an exemplary embodiment;

FIG. 9 illustrates an exemplary embodiment of a detailed layout of the data line driver illustrated in FIG. 8; and

FIG. 10 illustrates a schematic block diagram of a data processing system according to an exemplary embodiment.

### DETAILED DESCRIPTION

Korean Patent Application No. 10-2010-0004644, filed on Jan. 19, 2010, in the Korean Intellectual Property Office, and entitled: “Data Line Driver and Apparatuses Having the Same,” is incorporated by reference herein in its entirety.

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural fauns as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

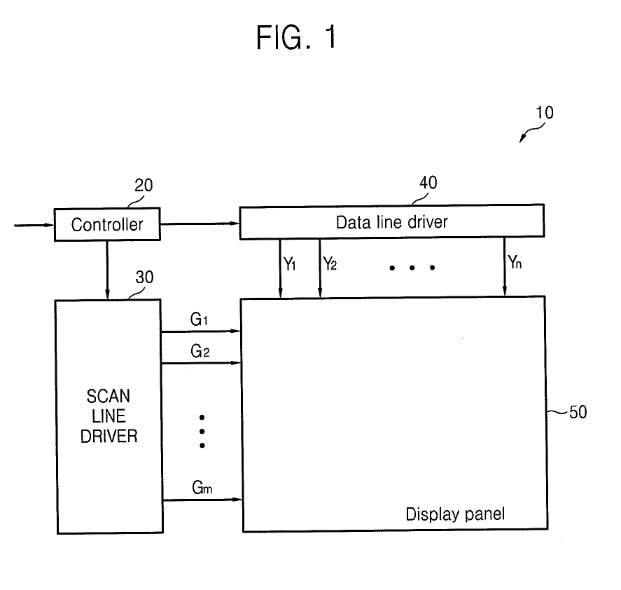

FIG. 1 is a schematic block diagram of a display device 10 including a data line driver 40, according to an exemplary embodiment. Referring to FIG. 1, the display device 10 includes a controller 20, a scan line driver 30, the data line driver 40, and a display panel 50. The display device 10 may be a part of a portable communication apparatus, such as a mobile telephone, a smart phone, a personal digital assistant (PDA), a tablet personal computer (PC), or a portable multimedia player (PMP), or a part of consumer equipment (CE) such as a monitor or a TV.

The controller 20 may receive a plurality of system control signals and image data, for example, RGB image data, from an external source and outputs a plurality of control signals and the image data in response to the system control signals. The controller 20 means any kind of controller capable of controlling at least one of an operation of the scan line driver 30, an operation of the data line driver 40, and an operation of the display panel 50.

The scan line driver 30, which is also called a gate line driver, may be connected to a plurality of scan lines (or gate lines) G₁ through Gₘ (where m denotes a natural number) and may sequentially supply scan signals (or driving signals) to the scan lines G₁ through Gₘ in response to at least one of the control signals output by the controller 20, for example, under the control of the controller 20.

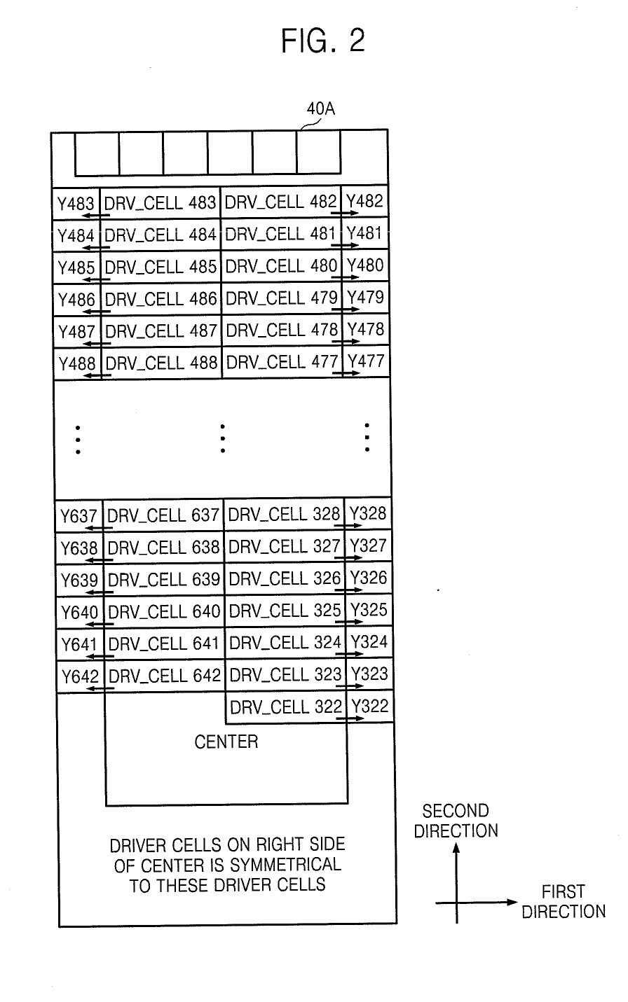

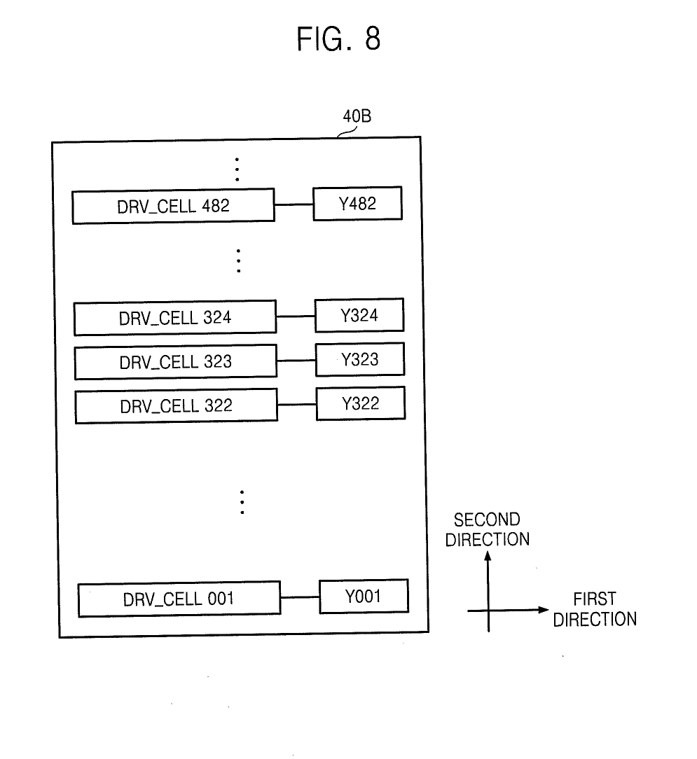

The data line driver 40, which is also called a source driver or a signal line driving circuit, may be connected to a plurality of data lines (or signal lines) Y₁ through Yₙ (where n denotes a natural number) and may supply analog image signals (or analog data signals) to the data lines Y₁ through Yₙ in response to at least one of the control signals output by the controller 20, for example, under the control of the controller 20. The data line driver 40 denotes a data line driver 40A of FIG. 2 or a data line driver 40B of FIG. 8. The data lines are also called channels. The scan line driver 30 and the data line driver 40 may be implemented as a single semiconductor chip or as independent semiconductor chips according to embodiments.

The display panel 50 may include a plurality of pixels, namely, n×m pixels, connected between the scan lines G₁ through Gₘ formed in a row direction of the display panel 50 and the data lines Y₁ through Yₙ formed in a column direction of the display panel 50. The display panel 50 may be a flat display panel such as a thin film transistor liquid crystal display (TFT-LCD) panel, a light emitting display (LED) panel, an organic LED (OLED) panel, Active Matrix Organic Light Emitting Diode (AMOLED) panel, or a plasma display panel (PDP).

FIG. 2 is a layout of the data line driver 40A included in the display device 10 illustrated in FIG. 1, according to an exemplary embodiment. Referring to FIG. 2, a data line driver 40A having a 2-column architecture (or a double column architecture) includes a plurality of driver cells arranged in a first direction (for example, a vertical direction or a short-edge direction).

The 2-column or double-column architecture denotes an architecture in which two driver cells that drive different data lines (for example, two driver cells DRV_CELL 323 and DRV_CELL 642 or two driver cells DRV_CELL 482 and DRV_CELL 483) are arranged to be vertically symmetrical with each other with respect to a second direction (for example, a horizontal direction or a long-edge direction) perpendicular to the first direction. The driver cells are also called channel drivers.

Some of the plurality of driver cells are arranged on the right side of a center CENTER where a logic control unit (not shown) is installed (or laid out), and the rest (for example, driver cells DRV_CELL 322 through DRV_CELL 642) are arranged on the left side of the center CENTER. The logic control unit may control respective operations of the plurality of driver cells in response to the control signals output by the controller 20 or control signals output by a processor (not shown) such as a central processing unit (CPU).

For simplicity of drawings or convenience of explanation, FIG. 2 illustrates only the driver cells DRV_CELL 322 through DRV_CELL 642 arranged on the left side of the center CENTER. According to the present embodiment, a pitch of each of the driver cells DRV_CELL 322 through DRV_CELL 642 is equal to a pitch of each of a plurality of output pads Y322 through Y642.

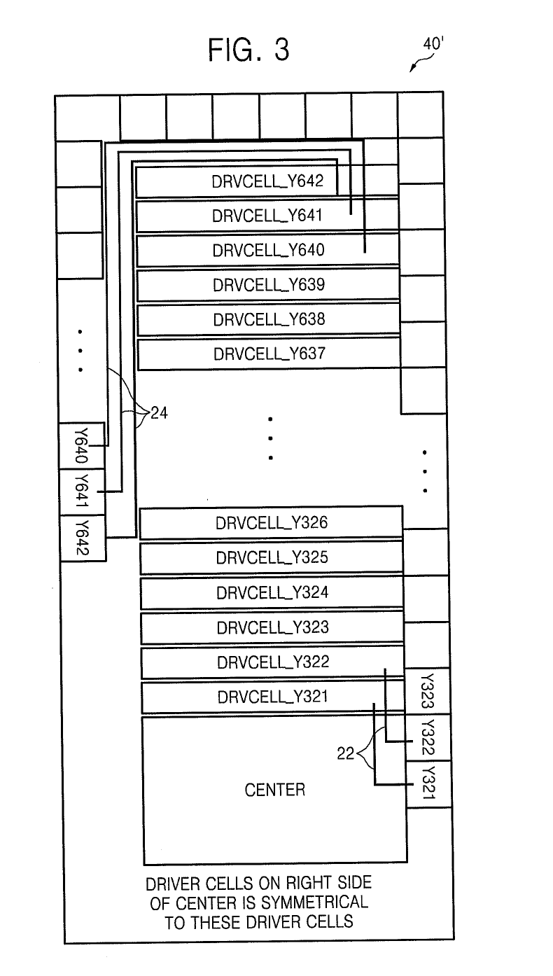

FIG. 3 is a layout of a conventional data line driver 40′. Referring to FIG. 3, the conventional data line driver 40′ includes a plurality of driver cells. Some of the plurality of driver cells are arranged on the right side of a center CENTER where a logic control unit (not shown) is installed, and the rest (for example, driver cells DRVCELL_Y321 through DRVCELL_Y642) are arranged on the left side of the center CENTER.

As illustrated in FIG. 3, a pitch of each of the driver cells DRVCELL_Y321 through DRVCELL_Y642 is different from that of each of a plurality of output pads Y321 through Y642. Accordingly, a plurality of output lines 22 and 24 are required to transmit signals respectively output from the driver cells DRVCELL_Y321 through DRVCELL_Y642, for example, from respective output buffers (not shown) of the driver cells DRVCELL_Y321 through DRVCELL_Y642, to the output pads Y321 through Y642, respectively. Accordingly, since the output lines 22 and 24 have different lengths, a characteristic deviation (for example, a slew rate or an output deviation voltage (DVO)) is generated between the driver cells DRVCELL_Y321 through DRVCELL_Y642, and an overall chip area of the conventional data line driver 40′ is increased due to routing of the output lines 22 and 24.

However, as illustrated in FIG. 2, if the pitch of each of the driver cells DRV_CELL 322 through DRV_CELL 642 is equal to the pitch of each of the output pads Y322 through Y642, the output lines 22 and 24 of FIG. 3 may not be needed. Therefore, routing of output lines is not generated, and thus the length of a long edge of the data line driver 40, for example, the length of the data line driver 40A of FIG. 2 in the second direction, may be reduced compared to the conventional data line driver 40′.

Moreover, since the lengths of output lines between the driver cells (for example, the driver cells DRV_CELL 322 through DRV_CELL 642) and the output pads (for example, the output pads Y321 through Y642) are identical in the data line driver 40A of FIG. 2, a characteristic deviation between the driver cells (for example, the driver calls DRV_CELL 322 through DRV_CELL 642) may be reduced or prevented.

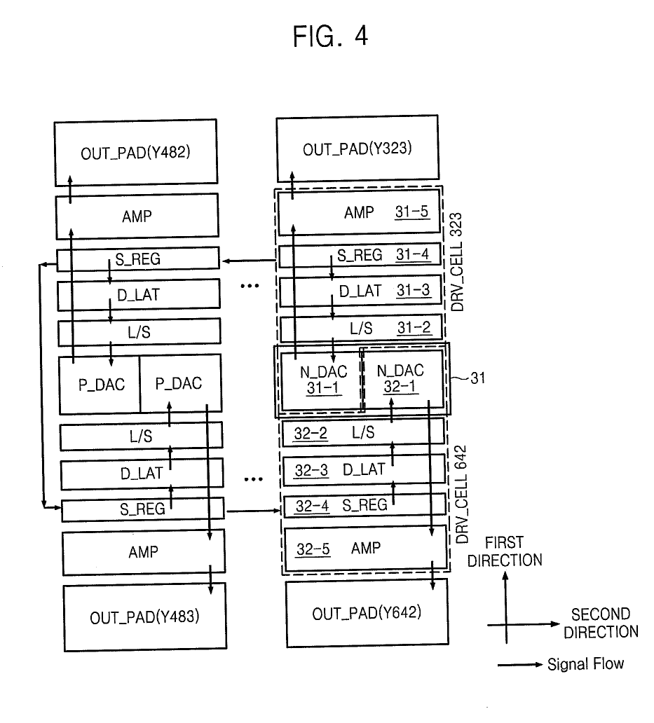

FIG. 4 is an embodiment of a detailed layout of the data line driver 40A illustrated in FIG. 2. Referring to FIGS. 2 and 4, a first driver cell DRV_CELL 323 including a first digital-analog converter (DAC) 31-1 and a second driver cell DRV_CELL 642 including a second DAC 32-1 are arranged to be vertically symmetrical with each other about a region defined by a decoder block 31.

The first DAC 31-1 and the second DAC 32-1 are both installed in the single decoder block 31 so as to be adjacent to each other on the left and right sides of the decoder block 31 in the first direction. A sum of the pitches of the first and second DACs 31-1 and 32-1 may be smaller than or equal to a pitch of a first output pad Y323. The pitch of the first output pad Y323 is equal to a pitch of a second output pad Y642. A pitch of a first driver cell DRV_CELL 323 is equal to a pitch of a second driver cell DRV_CELL 642. The pitch of the first output pad Y323 is equal to the pitch of the first driver cell DRV_CELL 323. Here, the meaning of “equal” denotes completely or substantially equal.

In some cases, the sum of the pitches of the first and second DACs 31-1 and 32-1 may be greater than the pitch of the first output pad Y323. Each of the first and second DACs 31-1 and 32-1 may include any electronic circuit that performs a multi-input single-output function. Accordingly, each of the first and second DACs 31-1 and 32-1 may be called a decoder.

Although the first and second DACs 31-1 and 32-1 of the same type, for example, each outputting a positive reference voltage (or a positive gamma voltage) or a negative reference voltage (or a negative gamma voltage), are illustrated in FIG. 4, the first and second DACs 31-1 and 32-1 may be different types. For example, the first DAC 31-1 may output a positive reference voltage, and the second DAC 32-1 may output a negative reference voltage.

The first driver cell DRV_CELL 323 includes a first output buffer 31-5 and a first signal transmission circuit which are sequentially disposed between the first output pad Y323 and the first DAC 31-1.

When the data line driver 40A is formed in the display device 10, the first output pad Y323 may be connected to a first data line. For example, the first signal transmission circuit, for example, a first shift register, may transmit a signal output from a signal transmission circuit, for example, a second shift register, of a previous stage driver cell to a signal transmission circuit, for example, a third shift register, of a next stage driver cell.

The first signal transmission circuit includes a first shift register 31-4, a first data latch (or a first data register) 31-3, and a first level shifter 31-2 which are sequentially disposed between the first output buffer (or an amplifier) 31-5 and the decoder block 31 including the first DAC 31-1.

The first shift register 31-4 and the first data latch 31-3 may be low-voltage devices. The first DAC 31-1, the first level shifter 31-2, and the first output buffer 31-5 may be high-voltage devices. The first shift register 31-4 sequentially shifts pulses in response to a start pulse for notifying an operation point of time, a transmission-direction control signal for controlling a data transmission direction, a shift clock signal, and the like, from an external source, and outputs the sequentially shifted pulses to the first data latch 31-3.

The first data latch 31-3 receives image data from an external source and stores the image data in response to the pulses received from the first shift register 31-4, for example, in response to latch clock signals, and outputs the stored image data to the first level shifter 31-2 in response to a clock signal received from an external source. The first level shifter 31-2 shifts the level of the image data received from the first data latch 31-3 and outputs level-shifted image data to the first DAC 31-1.

The first DAC 31-1 outputs a reference voltage corresponding to the level-shifted image data received from the first level shifter 31-2 from among reference voltages input from an external source, for example, gamma voltages (or grayscale voltages). In other words, the first DAC 31-1 may select the reference voltage corresponding to the level-shifted image data.

The first output buffer 31-5 buffers (or amplifies) the reference voltage output from the first DAC 31-1 and outputs the buffered (or amplified) reference voltage to the first data line via the first output pad Y323. The second driver cell DRV_CELL 642 includes a second output buffer 32-5 and a second signal transmission circuit which are sequentially disposed between the second output pad Y642 and the decoder block 31 including the second DAC 32-1. The second output pad Y642 is connected to a second data line.

The second signal transmission circuit includes a second shift register 32-4, a second data latch 32-3 (or a second data register 32-3), and a second level shifter 32-2 which are sequentially disposed between the second output buffer 32-5 and the decoder block 31. The second shift register 32-4 operates similarly with the first shift register 31-4, the second data latch 32-3 operates similarly with the first data latch 31-3, and the second level shifter 32-2 operates similarly with the first level shifter 31-2.

The second DAC 32-1 outputs a reference voltage corresponding to level-shifted image data received from the second level shifter 32-2 from among the reference voltages input from an external source, for example, the gamma voltages (or the grayscale voltages). The second output buffer 32-5 buffers (or amplifies) the reference voltage output from the second DAC 32-1 and outputs the buffered (or amplified) reference voltage to the second data line via the second output pad Y642.

In the present embodiment, the first driver cell DRV_CELL 323 and the second driver cell DRV_CELL 642 are arranged to be symmetrical with each other with respect to the second direction, for example, to be vertically symmetrical, about a circuit region defined by the decoder block 31. Thus, a pitch of each of the first and second driver cells DRV_CELL 323 and DRV_CELL 642 may be less than or equal to a sum of pitches of two conventional driver cells (for example, the driver cells DRVCELL_Y321 and DRVCELL_Y642) of FIG. 3.

For example, if the pitch of each of the first and second driver cells DRV_CELL 323 and DRV_CELL 642 increases to two times a pitch of a conventional driver cell (for example, the driver cell DRVCELL_Y321) and the layout height of each of the first and second output buffers 31-5 and 32-5 and the layout height of each of the first and second signal transmission circuits are decreased, the data line driver 40 may have a reduced length in the first direction, for example, a reduced length of a short edge. Accordingly, the data line driver 40 having the double column architecture may simultaneously shrink both the length in the second direction (for example, the length of the long edge) and the length in the first direction (for example, the length of the short edge).

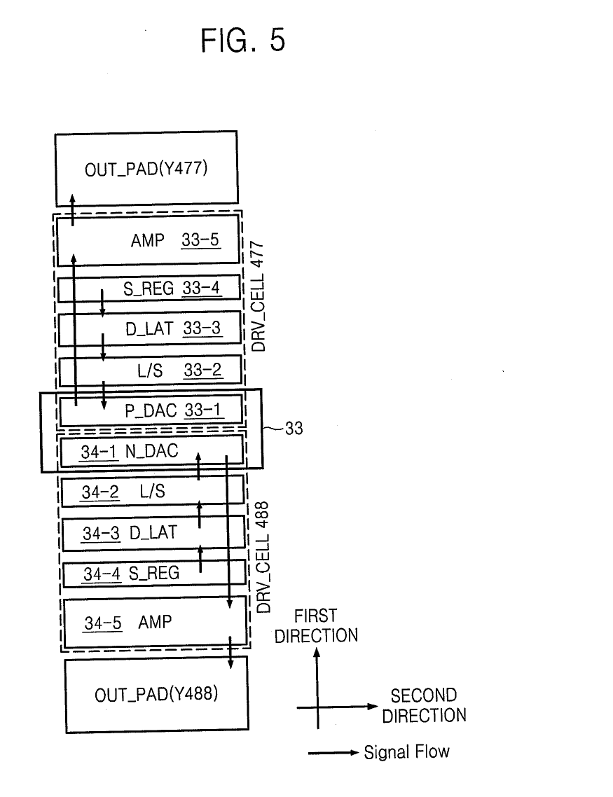

FIG. 5 is another embodiment of a detailed layout of the data line driver 40A illustrated in FIG. 2. Referring to FIGS. 2 and 5, a first driver cell DRV_CELL 477 including a first DAC 33-1 and a second driver cell DRV_CELL 488 including a second DAC 34-1 are arranged to be symmetrical with respect to the second direction, for example, vertically, about a circuit region defined by a decoder block 33.

The first DAC 33-1 (also indicated by P_DAC) and the second DAC 34-1 (also indicated by N_DAC) are both embodied within the single decoder block 33 so as to be vertically symmetrical with each other with respect to the second direction. Pitches of the first and second DACs 33-1 and 34-1 may be less than or equal to a pitch of the first or second output pad Y477 or Y488. In some cases, the first DAC 33-1 may be a DAC that outputs a positive reference voltage, and the second DAC 34-1 may be a DAC that outputs a positive reference voltage. According to the double-column architecture, the pitch of the first driver cell DRV_CELL 477 is equal to the pitch of the second driver cell DRV_CELL 488. The pitch of the first driver cell DRV_CELL 477 is equal to the pitch of each of the first and second output pads Y477 and Y488.

The first driver cell DRV_CELL 477 includes a first output buffer 33-5 and a first signal transmission circuit which are sequentially disposed between the first output pad Y477 and the first DAC 33-1. The first output pad Y477 is connected to a first data line. The first signal transmission circuit includes a first shift register 33-4, a first data latch 33-3, and a first level shifter 33-2 which are sequentially disposed between the first output buffer 33-5 and the first DAC 33-1.

The second driver cell DRV_CELL 488 includes a second output buffer 34-5 and a second signal transmission circuit which are sequentially disposed between the second output pad Y488 and the second DAC 34-1. The second output pad Y488 is connected to a second data line. The second signal transmission circuit includes a second shift register 34-4, a second data latch 34-3, and a second level shifter 34-2 which are sequentially disposed between the second output buffer 34-5 and the second DAC 34-1.

The first and second shift registers 33-4 and 34-4 operate in the same manner as the shift register 31-4, the first and second data latches 33-3 and 34-3 operate in the same manner as the data latch 31-3, and the first and second level shifters 33-2 and 34-2 operate in the same manner as the level shifter 31-2.

The first DAC 33-1 outputs a reference voltage corresponding to level-shifted image data received from the first level shifter 33-2 from among reference voltages input from an external source to the first output buffer 33-5. The first output buffer 33-5 may buffer (or amplify) the reference voltage output from the first DAC 33-1 and output the buffered (or amplified) reference voltage to the first data line via the first output pad Y477. The second DAC 34-1 outputs a reference voltage corresponding to level-shifted image data received from the second level shifter 34-2 from among the reference voltages input from an external source to the second output buffer 34-5. The second output buffer 34-5 may buffer (or amplify) the reference voltage output from the second DAC 34-1 and output the buffered (or amplified) reference voltage to the second data line via the second output pad Y488.

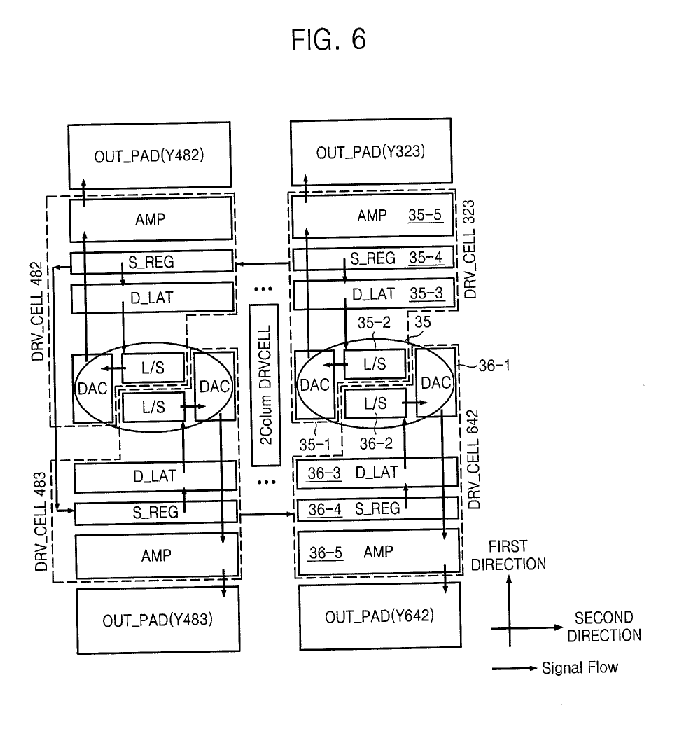

FIG. 6 is another embodiment of a detailed layout of the data line driver 40A illustrated in FIG. 2. Referring to FIGS. 2 and 6, the data line driver 40A includes a first driver cell DRV_CELL 323 and a second driver cell DRV_CELL 642 which are arranged to be symmetrical with each other with respect to the second direction, for example, a horizontal direction. The first driver cell DRV_CELL 323 and the second driver cell DRV_CELL 642 are arranged in the first direction, for example, a vertical direction.

A first DAC 35-1, a first level shifter 35-2, a second level shifter 36-2, and a second DAC 36-1 are disposed on a single circuit region 35.

The first driver cell DRV_CELL 323 includes the first DAC 35-1 for supplying a digital-to-analog converted signal to a first data line, and the first level shifter 35-2 for supplying a level-shifted signal to the first DAC 35-1. The second driver cell DRV_CELL 642 includes the second DAC 36-1 for supplying a digital-to-analog converted signal to a second data line, and the second level shifter 36-2 for supplying a level-shifted signal to the second DAC 36-1.

The first and second level shifters 35-2 and 36-2 adjacent to each other in the first direction are disposed between the first and second DACs 35-1 and 36-1 arranged in the second direction perpendicular to the first direction. According to this structure, a length of the data line driver 40A illustrated in FIG. 6 in the first direction may be reduced by a sum of the length of the first level shifter 31-2 or 33-2 of FIG. 4 or 5 in the first direction and the length of the second level shifter 32-2 or 34-2 of FIG. 4 or 5 in the first direction.

Shifter registers 35-4 and 36-4 operate in substantially the same manner as that in which the shifter register 31-4 operates. Data latches 35-3 and 36-3 operate in substantially the same manner as that in which the data latch 31-3 operates. The first and second level shifters 35-2 and 36-2 operate in substantially the same manner as that in which the level shifter 31-2 operates.

The first DAC 35-1 outputs a reference voltage corresponding to level-shifted image data received from the first level shifter 35-2 from among reference voltages input from an external source to the first output buffer 35-5. The first output buffer 35-5 may buffer (or amplify) the reference voltage output from the first DAC 35-1 and output the buffered (or amplified) reference voltage to the first data line via the first output pad Y323.

The second DAC 36-1 outputs a reference voltage corresponding to level-shifted image data received from the second level shifter 36-2 from among the reference voltages input from an external source to the second output buffer 36-5. The second output buffer 36-5 may buffer (or amplify) the reference voltage output from the second DAC 36-1 and output the buffered (or amplified) reference voltage to the second data line via the second output pad Y642. A sum of the pitches of the first DAC 35-1, the first level shifter 35-2, and the second DAC 36-1 may be less than or equal to a pitch of the first or second output pad Y323 or Y642.

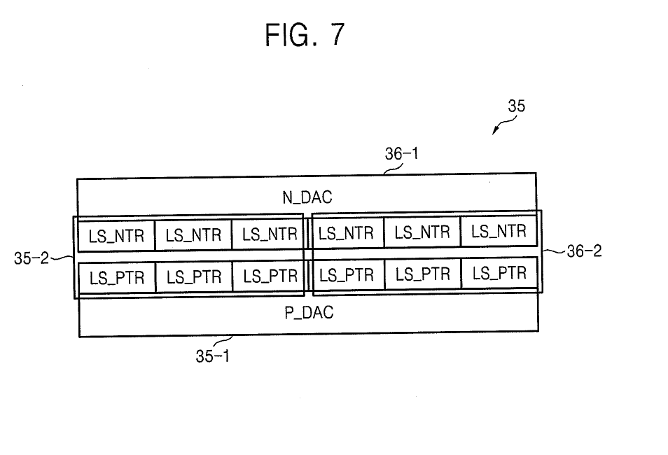

FIG. 7 illustrates an example of the circuit region 35 illustrated in FIG. 6. Referring to FIGS. 6 and 7, the first level shifter 35-2 includes a plurality of PMOS transistors LS_PTR and a plurality of NMOS transistors LS_NTR. The plurality of PMOS transistors LS_PTR are embodied (or laid out) within a first region, for example, a first well, including the first DAC 35-1, and the plurality of NMOS transistors LS_NTR are embodied (or laid out) within a second region, for example, a second well, including the second DAC 36-1.

The second level shifter 36-2 includes a plurality of PMOS transistors LS_PTR and a plurality of NMOS transistors LS_NTR. The plurality of PMOS transistors LS_PTR are embodied (or laid out) within the first region, for example, the first well, including the first DAC 35-1, and the plurality of NMOS transistors LS_NTR are embodied (or laid out) within the second region, for example, the second well, including the second DAC 36-1. In other words, the data line driver 40A may maximize a practical space use due to the sharing of the first or second region.

FIG. 8 is a layout of the data line driver 40B included in the display device 10 illustrated in FIG. 1, according to an exemplary embodiment. FIG. 8 illustrates a 1-column driver cell structure in contrast with the 2-column driver cell structure of FIG. 2. Referring to FIG. 8, a data line driver 40B having the 1-column structure includes at least a plurality of driver cells DRV_CELL 001 through DRV_CELL 482, arranged in the first direction, and a plurality of output pads Y001 through Y482, respectively connected to the driver cells DRV_CELL 001 through DRV_CELL 482.

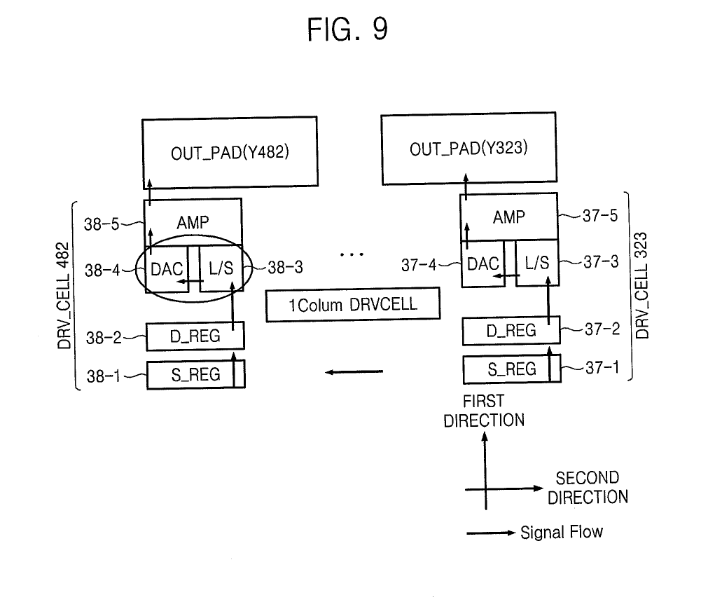

FIG. 9 is an embodiment of a detailed layout of the data line driver 40B illustrated in FIG. 8. The first driver cell DRV_CELL 323 includes a first shift register 37-1, a first data latch (or a first data register) 37-2, a first level shifter 37-3, a first DAC 37-4, a first output buffer (or an amplifier) 37-5, and a first output pad Y323.

The first level shifter 37-3 and the first DAC 37-4 adjacent to each other in the second direction are disposed between the first data latch 37-2 and the first output buffer 37-5 arranged in the first direction. In other words, as the first level shifter 37-3 and the first DAC 37-4 are arranged to be adjacent to each other in the second direction, a length of the data line driver 40B in the first direction is less than that of a data line driver in which the first level shifter 37-3 and the first DAC 37-4 are arranged in the first direction.

The first shift register 37-1 generates a first latch clock signal. The first data latch 37-2 latches image data in response to the first latch clock signal and transmits the latched image data to the first level shifter 37-3 in response to a clock signal. The first level shifter 37-3 shifts the level of the image data received from the first data latch 37-2 and outputs level-shifted image data to the first DAC 37-4.

The first DAC 37-4 outputs a reference signal corresponding to the level-shifted image data from among a plurality of reference signals to the first output buffer 37-5. The first output buffer 37-5 buffers (or amplifies) the reference signal output from the first DAC 37-4 and outputs the buffered (or amplified) reference signal to the first data line via the first output pad Y323.

The second shift register 38-1 generates a second latch clock signal. The second data latch 38-2 latches image data in response to the second latch clock signal and transmits the latched image data to the second level shifter 38-3 in response to a clock signal. The second level shifter 38-3 shifts the level of the image data received from the second data latch 38-2 and outputs level-shifted image data to the second DAC 38-4.

The second DAC 38-4 outputs a reference signal corresponding to the level-shifted image data from among the plurality of reference signals to the second output buffer 38-5. The second output buffer 38-5 buffers (or amplifies) the reference signal output from the second DAC 38-4 and outputs the buffered (or amplified) reference signal to the second data line via a second output pad Y482.

A sum of the pitches of the first level shifter 37-3 and the first DAC 37-4 is less than or equal to a pitch of the first output pad Y323. Also, a sum of the pitches of the second level shifter 38-3 and the second DAC 38-4 is less than or equal to a pitch of the second output pad Y482.

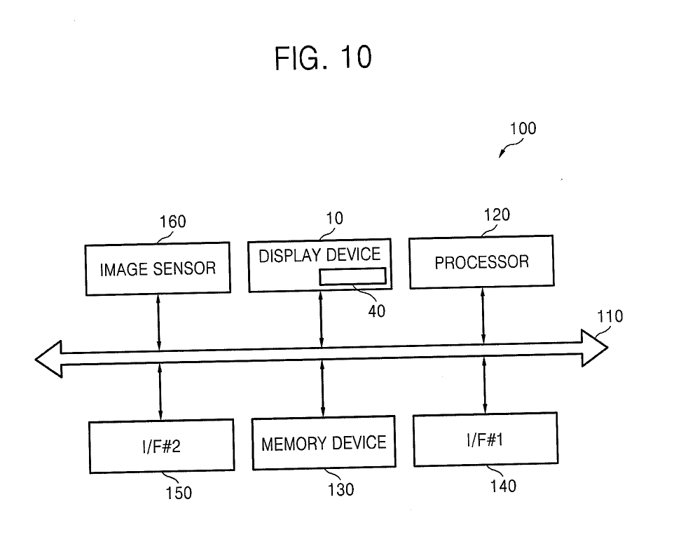

FIG. 10 is a schematic block diagram of a data processing system 100 according to an exemplar embodiment. Referring to FIG. 10, the data processing system 100 such as a display system includes the display device 10 and a processor 120 which are connected to a system bus 110. The processor 120 generates a plurality of system control signals and transmits the system control signals to the display device 10.

As illustrated in FIG. 1, the display device 10 includes the display panel 50 including the first and second data lines, and the controller 20 which generates, in response to the system control signals output by the processor 120, a plurality of control signals for controlling the operations of the scan line driver 30 and the data line driver 40.

The data line driver 40A having the 2-column architecture includes driver cells for driving respective data lines in response to the control signals output from the controller 20, as described above with reference to FIGS. 4 through 6. The processor 120 may control a write operation (or program operation), a read operation, a verification read operation, or an erase operation of a memory device 130.

The memory device 130 may perform any operation related with data input/output, such as a write operation (or program operation), a read operation, a verification read operation, a program operation, or an erase operation, under the control of the processor 120. The memory device 130 may be a volatile memory device or a nonvolatile memory device (for example, a flash memory, or a resistive RAM (RRAM) such as a phase-change random access memory (PRAM)). The memory device 130 may also be a hard disk drive or a solid state disk.

If a portable application is used as the data processing system 100, the data processing system 100 may further include a battery (not shown) for supplying operational power to the memory device 130, the processor 120, and the display device 10. Examples of the portable application include a portable computer, a digital camera, a tablet PC, a PDA, a cellular telephone, an MP3 player, a PMP, an automotive navigation system, a game player, an electronic dictionary, etc.

The data processing system 100 may further include a first interface, for example, an input/output device 140, to transmit and receive data to and from an external data-processing device, for example, a PC. If the data processing system 100 is a wireless system, the data processing system 100 may further include a second interface, for example, a wireless interface 150. In this case, the wireless interface 150 may be connected to the processor 120 and transmit and receive data to and from an external wireless device (not shown) wirelessly via the system bus 110. For example, the processor 120 processes data output from the wireless interface 150 and stores processed data to the memory device 120. The processor 1520 read data stored in the memory device 130 and transmits the read data to the wireless interface 150. Also, the processor 120 may display data received through the input/output device 140 or the wireless interface 150, by using the display device 10.

The wireless system may be a PDA, a wireless portable computer, a digital camera, or a Radio-Frequency IDentification (RFID) system. The wireless system may also be a Wireless Local Area Network (WLAN) system or a Wireless Personal Area network (WPAN) system.

If the data processing system 100 is an image pick-up (or processing) device, the data processing system 100 may further include an image sensor 160 which converts an optical signal into an electrical signal. The image sensor 160 may be an image sensor using a charge-coupled device (CCD) or a complementary metal oxide semiconductor (CMOS) image sensor manufactured using a CMOS process. In this case, the data processing system 100 may display data output from the image sensor 160 by using the display device 10 under the control of the processor 120.

In this case, the data processing system 100 may be a digital camera or a mobile phone to which a digital camera is attached. The data processing system 100 may also be a satellite system to which a camera is attached. The data processing system 100 may transmit the data output from the image sensor 160 to outside via the input/output device 140, via the wireless interface 150, or via both of them, under the control of the processor 120. The data processing system 100 may process the data output from the image sensor 160 and store the data in the memory device 130, under the control of the processor 120.

The data processing system 100 may not only include the display device 10 and the processor 120 but also include at least one of the memory device 130, the input/output device 140, the wireless interface 150, and the image sensor 160 according to an implemented system.

Without intending to be bound by this theory, a data line driver having a new layout according to one or more exemplary embodiments may reduce lengths of the data line driver in the first and second directions, particularly, the length in the first direction. This leads to an increase in the number of channels used in the data line driver. Moreover, the data line driver having a new layout according to one or more exemplary embodiments may include driver cells and output pads which are arranged at the same or substantially the same pitch. Therefore, a characteristic deviation between the driver cells formed in the data line driver may be reduced or prevented.

While the present invention has been particularly shown and described with reference to exemplary embodiments thereof, it will be understood that various changes in form and details may be made therein without departing from the spirit and scope of the following claims.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A data line driver, comprising:
a first driver cell configured to drive a first data line connected to a first output pad, the first driver cell including:
a first data register configured to latch first image data in response to a first latch clock signal;
a first level shifter connected to the first data register;
a first digital-analog converter (DAC) connected to the first level shifter; and
a first amplifier connected between the first DAC and the first output pad,
wherein the first data register and the first amplifier are arranged in a first direction, the first level shifter and the first DAC are arranged adjacent to each other in a second direction and are arranged between the first data register and the first amplifier, the second direction being perpendicular to the first direction.

2. The data line driver as claimed in claim 1, wherein a sum of a pitch of the first level shifter and a pitch of the first DAC is less than or equal to a pitch of the first output pad.

3. The data line driver as claimed in claim 1, further comprising a second driver cell configured to drive a second data line connected to a second output pad, the second driver cell including:
a second data register disposed in the first direction and configured to latch second image data in response to a second latch clock signal;
a second level shifter connected to the second data register;
a second DAC connected to the second level shifter; and
a second amplifier disposed in the first direction and connected between the second DAC and the second output pad,
wherein the first level shifter and the second level shifter are connected between the first DAC and the second DAC.

4. The data line driver as claimed in claim 3, wherein the first level shifter and the second level shifter are arranged adjacent to each other to be symmetrical with each other with respect to the second direction.

5. The data line driver as claimed in claim 3, wherein a sum of a pitch of the first DAC, a pitch of the first level shifter, and a pitch of the second DAC is less than or equal to a pitch of the first output pad or a pitch of the second output pad.

6. The data line driver as claimed in claim 3, wherein the first driver cell and the second driver cell are arranged to be symmetrical with each other with respect to the second direction.

7. A data line driver, comprising:
a first driver cell including a first DAC configured to supply a digital-to-analog converted signal to a first data line, and a first level shifter configured to supply a level-shifted signal to the first DAC; and
a second driver cell including a second DAC configured to supply a digital-to-analog converted signal to a second data line, and a second level shifter configured to supply a level-shifted signal to the second DAC,
wherein the first level shifter and the second level shifter are arranged adjacent to each other in a first direction and are disposed between the first DAC and the second DAC, and the first DAC and the second DAC are arranged in a second direction perpendicular to the first direction.

8. The data line driver as claimed in claim 7, wherein the first driver cell and the second driver cell are arranged adjacent to each other to be symmetrical with each other with respect to the second direction.

9. The data line driver as claimed in claim 7, wherein:
the first driver cell further includes:
a first amplifier configured to amplify an output signal of the first DAC; and
a first output pad configured to supply a signal corresponding to a result of the amplification by the first amplifier to the first data line;
the second driver cell further includes:
a second amplifier configured to amplify an output signal of the second DAC; and
a second output pad configured to supply a signal corresponding to a result of the amplification by the second amplifier to the second data line,
wherein a sum of a pitch of the first DAC, a pitch of one of the first and second level shifters, and a pitch of the second DAC is less than or equal to a pitch of the first or second output pad.

10. A display device, comprising:
the data line driver of claim 1; and
a panel including the first data line.

11. The display device as claimed in claim 10, wherein:
the panel further includes a second data line; and
the data line driver further includes a second driver cell configured to drive a second data line connected to a second output pad,
the second driver cell includes:
a second data register disposed in the first direction and configured to latch second image data in response to a second latch clock signal;
a second level shifter connected to the second data register;
a second DAC connected to the second level shifter; and
a second amplifier disposed in the first direction and connected between the second DAC and the second output pad,
wherein the first level shifter and the second level shifter are connected between the first DAC and the second DAC.

12. The display device as claimed in claim 11, wherein the first level shifter and the second level shifter are arranged adjacent to each other to be symmetrical with each other with respect to the second direction.

13. The display device as claimed in claim 11, wherein a sum of a pitch of the first DAC, a pitch of the first level shifter, and a pitch of the second DAC is less than or equal to a pitch of the first output pad or a pitch of the second output pad.

14. The display device as claimed in claim 11, wherein the first driver cell and the second driver cell are arranged to be symmetrical with each other with respect to the second direction.

15. A display device comprising:
the data line driver as claimed in claim 7; and
a panel including the first data line and the second data line.

16. The display device as claimed in claim 15, wherein the first driver cell and the second driver cell are arranged to be symmetrical with each other with respect to the second direction.

17. The display device as claimed in claim 15, wherein:
the first driver cell further includes:
a first amplifier configured to amplify an output signal of the first DAC; and
a first output pad configured to supply a signal corresponding to a result of the amplification by the first amplifier to the first data line;
the second driver cell further includes:
a second amplifier configured to amplify an output signal of the second DAC; and
a second output pad configured to supply a signal corresponding to a result of the amplification by the second amplifier to the second data line,
wherein a sum of a pitch of the first DAC, a pitch of one of the first and second level shifters, and a pitch of the second DAC is less than or equal to a pitch of the first or second output pad.

18. A display system comprising:
the data line driver as claimed in claim 1;
a controller configured to control an operation of the data line driver; and
a panel including the first data line.

19. The display system as claimed in claim 18, wherein:
the panel further includes a second data line; and
the data line driver further includes a second driver cell configured to drive a second data line connected to a second output pad,
wherein the second driver cell includes:
a second data register disposed in the first direction and configured to latch second image data in response to a second latch clock signal;
a second level shifter connected to the second data register;
a second DAC connected to the second level shifter; and
a second amplifier disposed in the first direction and connected between the second DAC and the second output pad,
wherein the first level shifter and the second level shifter are connected between the first DAC and the second DAC.

20. A display system comprising:
the data line driver as claimed in claim 7;
a controller configured to control an operation of the data line driver; and
a panel including the first data line.

21. The display system as claimed in claim 20, wherein:
the first driver cell further includes:
a first amplifier configured to amplify an output signal of the first DAC; and
a first output pad configured to supply a signal corresponding to a result of the amplification by the first amplifier to the first data line;
the second driver cell further includes:
a second amplifier configured to amplify an output signal of the second DAC; and
a second output pad configured to supply a signal corresponding to a result of the amplification by the second amplifier to the second data line,
wherein a sum of a pitch of the first DAC, a pitch of one of the first and second level shifters, and a pitch of the second DAC is less than or equal to a pitch of the first or second output pad.
